(19) United States
(12) Patent Application Publication
(10) Pub. No.: US 2003/0224265 A1
(43) Pub. Date: Dec. 4, 2003

(54) System and method for reducing photoresist photo-oxidative degradation in 193 nm photolithography

(76) Inventor: Uzodinma Okoroanyanwu, Mountain View, CA (US)

Correspondence Address: David A. Blumenthal, Foley & Lardner, Suite 3500, 2029 Century Park East, Los Angeles, CA, 90067-3021, US

(21) Appl. No.: 10/017,871

(22) Filed: Dec. 11, 2001

(51) Int. Cl. G03F 7/20; G03F 7/26; G03B 27/42; G03B 27/54; G03B 27/32

(52) U.S. Cl. 430/30; 430/311; 430/322; 430/327; 355/53; 355/67; 355/77; 430/961

(57) ABSTRACT

An exposure section of a 193 nm photolithography system is purged with a purge gas containing substantially no oxygen, such as nitrogen or an inert gas. This prevents oxidation of photoresist by photo-induced oxygen species that are produced in conventional 193 nm systems purged by clean dry air. A scanner and a stepper of the system are preferably calibrated to the optical properties of the purge gas. A protective layer may be provided over the photoresist to further protect the photoresist.

### BACKGROUND OF THE INVENTION

1. Field of the Invention

Embodiments of the invention pertain to photolithography exposure systems.

2. Background Technology

Photolithography is a process by which a pattern is formed during fabrication of an integrated circuit. In conventional photolithography, a substrate is coated with a radiation-sensitive photoresist. The photoresist is exposed to radiation that is projected through a reticle containing a pattern to be formed on the substrate. Exposure of the photoresist to the radiation causes the exposed area to become either more or less soluble (depending on the photoresist chemistry) in a particular solvent developer. As a result, the photoresist receives the pattern of radiation that is formed by projection through the reticle. The unwanted areas of the pattern are then removed in a developing process. Conventional projection lithography processes are either “bright field” processes, in which areas to be removed are exposed to radiation, or “dark field” processes, in which areas to be retained are exposed to radiation. A processing step such as etching, diffusion, implantation or deposition is then performed using the photoresist pattern to selectively prevent the effects of the processing step. The remaining photoresist is subsequently removed in a stripping process.

FIG. 1 illustrates a conventional 193 nm projection lithography system 100. The lithography system 100 projects a pattern of radiation onto substrate 102 that is supported by a stage 120. The substrate 102 typically comprises a semiconductor wafer and may also comprise layers of additional materials, devices, and structures. The substrate is coated with a layer of photoresist that receives patterns projected by the lithography system.

The lithography system 100 includes a 193 nm radiation source 112, typically a 6.4 eV ArF laser. A condenser lens assembly 114 focuses the radiation onto a reticle 116 which has a pattern imprinted thereon. An objective lens assembly 118 focuses the pattern from the reticle 116 onto the substrate 102. In various types of lithography systems, the stage may be moved and the reticle may be moved to scan the reticle pattern over the entire substrate.

A barrier 122 isolates an exposure section 110 of the lithography system from the rest of the lithography system The exposure section 110 is purged with clean dry air directed toward the substrate during exposure to prevent contaminants created during exposure from being deposited on the objective lens. The remainder of the lithography system typically contains an atmosphere comprised of nitrogen and oxygen.

### SUMMARY OF THE DISCLOSURE

Embodiments of the invention may provide improved photolithography by reducing oxidation of photoresist that occurs in conventional 193 nm lithography systems as a result of radiation induced oxidizing agents. In accordance with one embodiment of the invention, a nitrogen purge is employed in the exposure section of the lithography system in place of the conventional clear dry air purge.

In accordance with one embodiment, a projection lithography system may comprise an exposure section, a stage located in the exposure section for supporting a photoresist coated substrate, a 193 nm radiation source, and a projection optical system for projecting a pattern of said 193 nm radiation toward said platform. The system may further comprise a gas delivery system for providing a purge gas to the exposure section. The gas delivery system may include a purge gas source that provides a purge gas containing substantially no oxygen. This reduces an amount of oxygen species induced by the 193 nm radiation in the exposure section. The purge gas is preferably nitrogen. The system may further include a stepper or scanner calibrated to the optical properties of the purge gas.

In a further embodiment of the invention, photolithography may be performed by providing a 193 nm lithography system including an exposure section, providing a substrate comprising a photoresist layer in the exposure section, and exposing the photoresist layer to 193 nm radiation while purging the exposure section with a purge gas containing substantially no oxygen. This reduces an amount of oxygen species induced by the 193 nm radiation in the exposure section. The purge gas is preferably nitrogen. Exposure may be preceded by calibrating a stepper or scanner of the lithography system to the optical properties of the purge gas.

The following description of preferred embodiments discloses additional features that may be implemented in conjunction with the various embodiments summarized above and in further combinations that will be apparent to those having ordinary skill in the art.

### BRIEF DESCRIPTION OF THE DRAWINGS

FIG. 1 shows a conventional 193 nm projection lithography system;

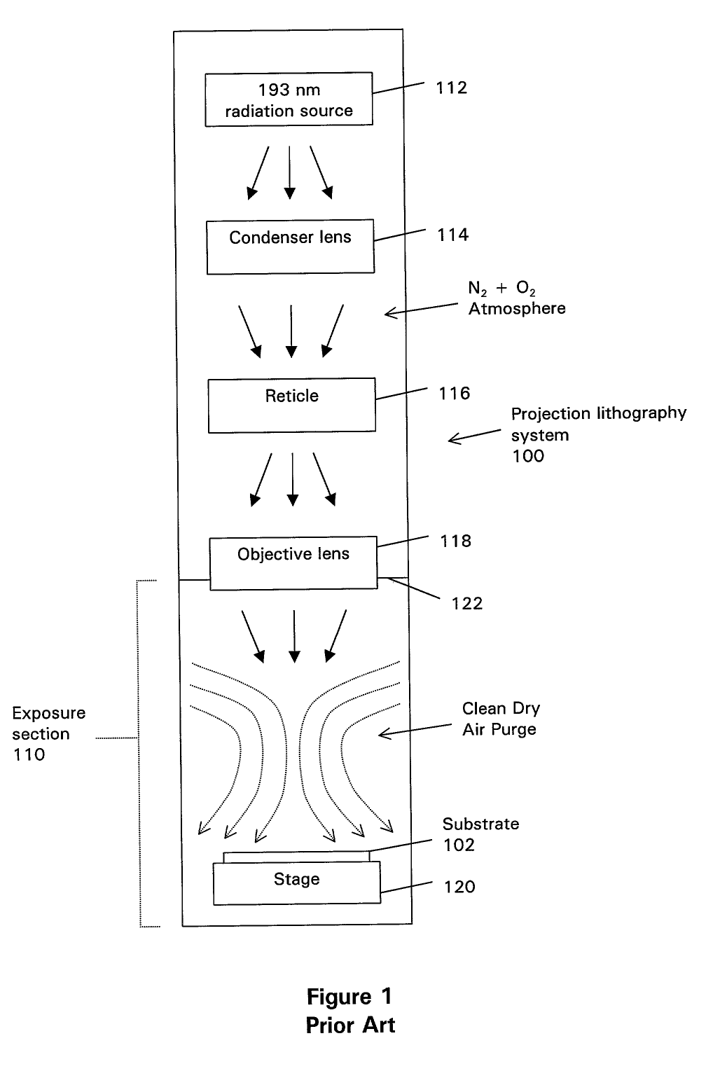

FIG. 2 shows potential energy curves of electronic states of molecular and atomic oxygen;

FIG. 3 shows photoresist degradation as a function of line width and clean dry air purge rates;

FIG. 4 shows Fourier Transform Infra-red spectra (FTIR) of photoresist chemical bond concentrations before and after ArF exposure in clean dry air;

FIG. 5 shows ArF laser exposure-induced resist film thickness loss as a function of initial resist film thickness;

FIG. 6 shows a projection lithography system in accordance with one embodiment of the invention;

FIG. 7 shows FTIR spectra illustrating relative photoresist degradation in dry air and nitrogen atmospheres;

FIG. 8 shows atomic % compositions of carbon and oxygen for exposed and unexposed photoresists in a variety of atmospheres;

FIG. 9 shows X-ray photo-emission spectra of photoresist carbon 1 s in photoresists exposed to ArF radiation in a nitrogen atmosphere;

FIG. 10 shows X-ray photo-emission spectra of photoresist carbon 1 s in photoresists exposed to ArF radiation in a dry air atmosphere; and

FIG. 11 shows FTIR spectra of a poly(fluoromethacrylic acid) top layer, a bare PAR700 photoresist layer, and a PAR700 photoresist layer protected by a layer of poly(fluoromethacrylic acid) top layer.

### DETAILED DESCRIPTION OF PREFERRED EMBODIMENTS

Photoresist exposed using conventional 193 nm exposure in a dry air atmosphere has been found to be susceptible to oxidation that results from several different mechanisms

Two of those mechanisms involve interaction of the 193 nm exposure radiation with the clean dry air atmosphere. A first of these mechanisms involves dissociation of molecular oxygen into atomic oxygen [O(³P)]:

$${O}_{2} ( {}_{}^{3}{\sum }{}_{g}^{-} ) {\to }^{λ = 193 nm} 2 O ( {}^{3} P )$$

A second mechanism involves excitation of molecular oxygen from its ground state to singlet oxygen:

$${O}_{2} ( {}_{}^{3}{\sum }{}_{g}^{-} ) {\to }^{λ = 193 nm} {}_{}^{1}{O}{}_{2}^{} ( {}_{}^{1}{Δ}{}_{g}^{} ) + {}_{}^{1}{O}{}_{2}^{} ( {}_{}^{1}{\sum }{}_{g}^{+} )$$

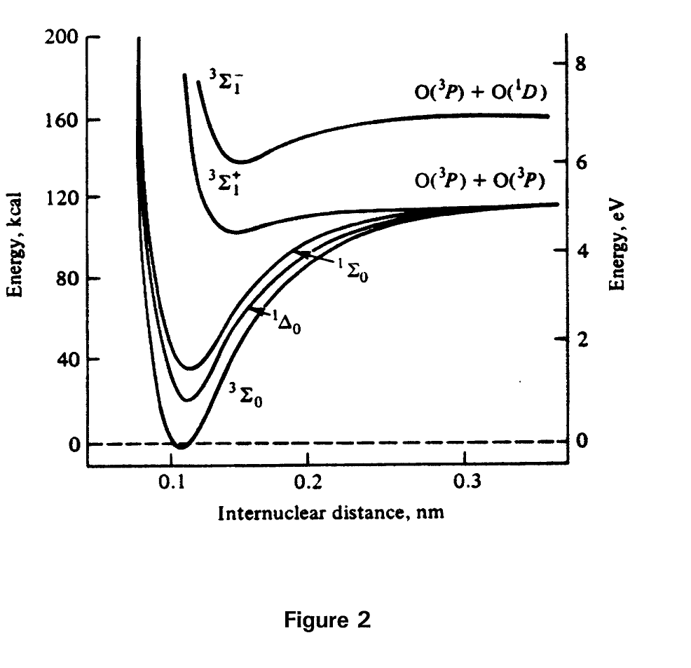

FIG. 2 illustrates the potential energy curves of electronic states of atomic oxygen that may be achieved through photo dissociation of molecular oxygen.

A third mechanism involves singlet oxygen formation in photoresist polymers through an energy transfer mechanism involving impurities or specially added sensitizers (S) (e.g. dyes):

$${S}_{0} {\to }^{hv} {}^{1} S ( {S}_{1} ) {\to }^{ISC} {}^{3} S ( {T}_{1} )$$

where ISC is the intersystem crossing:

¹S+O₂→³S+¹O₂(¹Δ_{g}, ¹Σ_{g}⁺)

¹S+O₂→S₀+¹O₂(¹Δ_{g}, ¹Σ_{g}⁺)

³S+O₂→S₀+¹O₂(¹Δ_{g}, ¹Σ_{g}⁺)

Once formed, these species mediate photo-oxidative degradation processes of resist polymers, including cross-linking, chain scission, oxidation, and other secondary reactions by free radical mechanisms, resulting in resist feature erosion, poor resist feature profiles, particularly under bright field illumination in full field scanners and steppers.

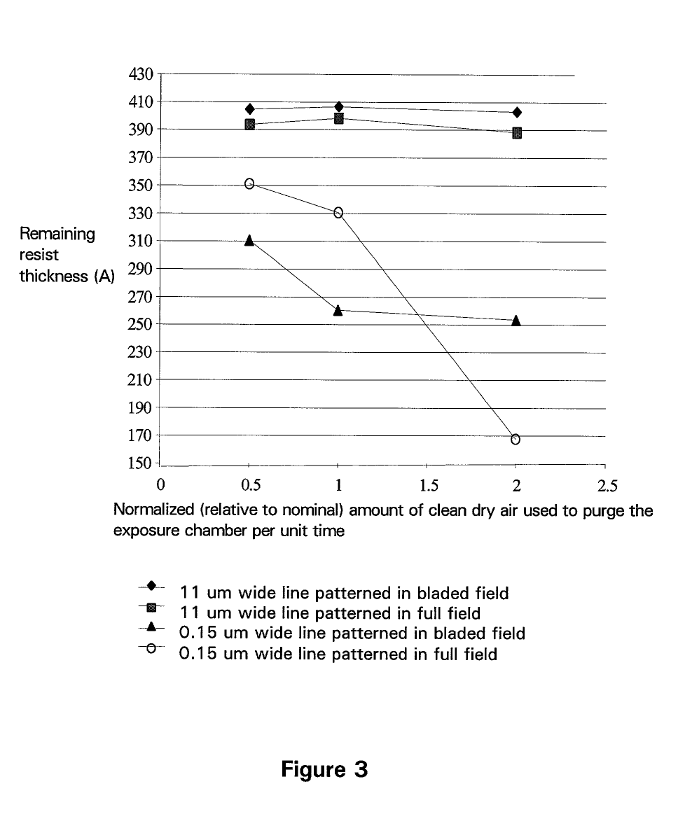

FIG. 3 is a plot of data showing rates of photoresist erosion as a function of the amount of clean dry air used to purge the exposure chamber of a 193 nm projection lithography system per unit of time. The data was generated using PAR700 resist (from Sumitomo Chemical Co.) and an ASML PAS5500/900 scanner, and resist thicknesses were measured using atomic force microscopy. The data show that resist thickness decreases for each test pattern as the amount of purge air per unit of time is increased. The data further show that more resist thickness erosion occurs for both the 11 μm and 0.15 μm lines with an increased purge air in full field exposures relative to bladed field exposures. This suggests that such erosion results from photo induced species rather than from scattered light.

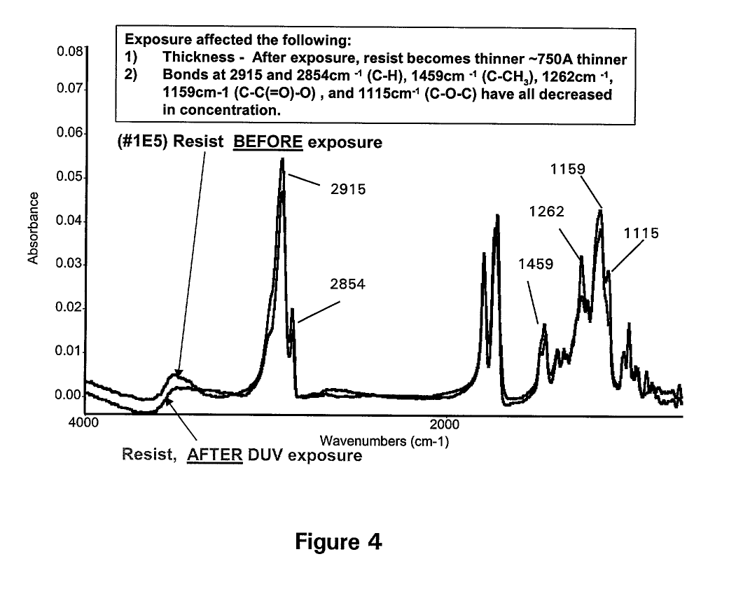

FIG. 4 shows Fourier Transform Infra-Red (FTIR) spectra for PAR700 photoresist, produced by Sumitomo Chemical Co., before and after exposure to 193 nm radiation in a clean dry air environment. Each signal indicates the concentration of specific chemical bonds in the resist. The plot shows significant decreases in signal intensity (e.g. concentration) of the signal representing the photoresist after exposure at the frequencies that correspond to the following bonds: C—H stretches (between 2915 and 2854 cm⁻¹), C—CH₃ stretches (1495 cm⁻¹), C—C(═O)—O stretches (around 1262 cm⁻¹ and 1159 cm⁻¹), and C−O—C stretches (around 1115 cm⁻¹). These decreases appear as divergences between the signals at the noted frequencies. The decreases in concentrations of these bonds is indicative of an increase in photo-oxidative degradation of the photoresist polymers.

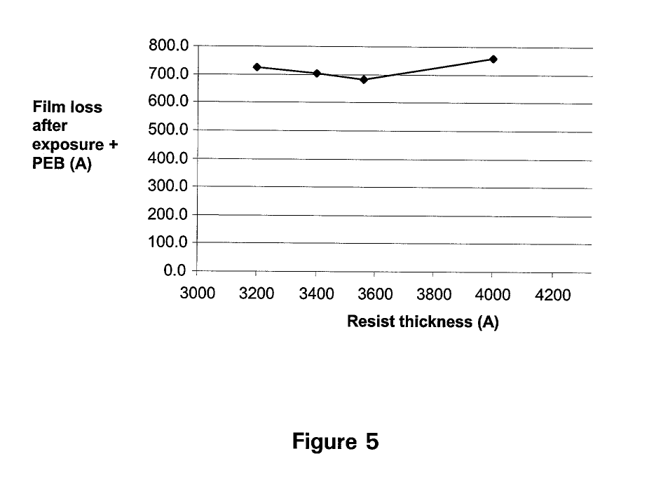

FIG. 5 shows ArF laser exposure-induced resist film thickness loss (as determined from FTIR measurements) as a function of initial resist film thickness. Film loss after exposure is relatively constant, indicating that the photo-oxidative degradation is not thickness dependent, and suggesting that the photo-oxidative degradation occurs at the surface rather than throughout the photoresist, giving rise to a gradient of deteriorated material across the specimen thickness.

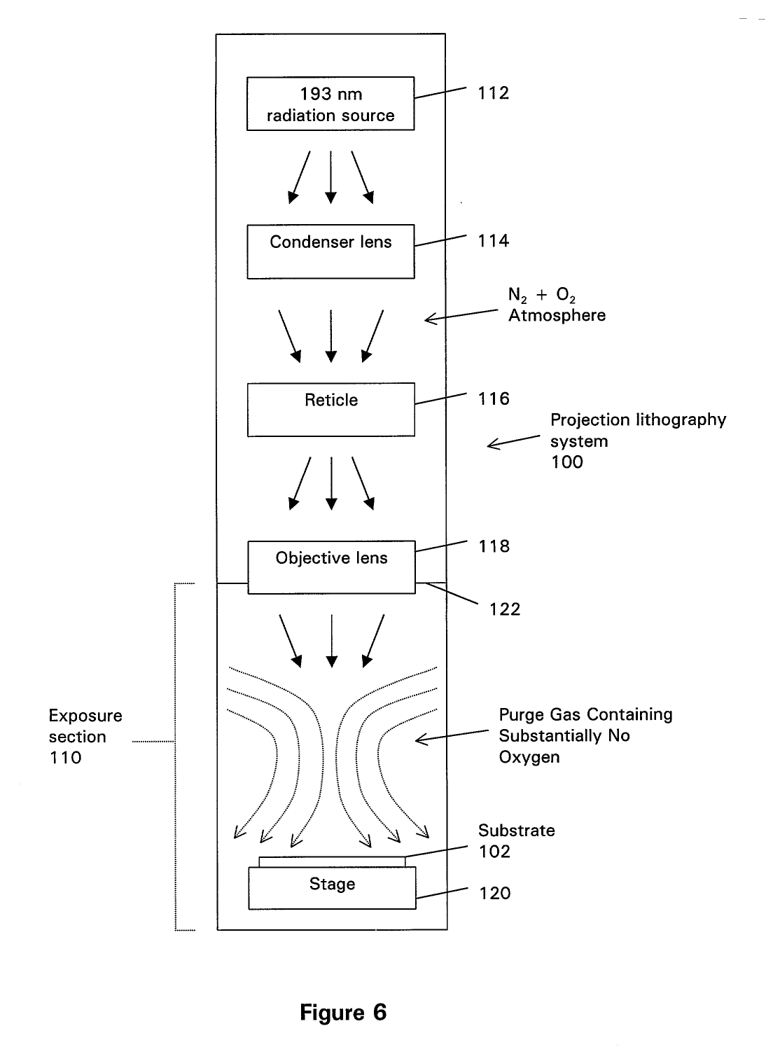

The oxidative mechanisms documented herein cause erosion and degradation of patterned photoresist features. To reduce these effects, in one embodiment in accordance with the invention, the clean dry air used to purge the conventional 193 nm lithography system is replaced with a purge gas containing substantially no oxygen. In a preferred embodiment, the purge gas is nitrogen (N₂). FIG. 6 shows in lithography system in accordance with the preferred embodiment. In this embodiment, the tanks of clean dry air gas that feed the purge system (not shown) in the conventional system are replaced with nitrogen tanks. In such systems it is typically necessary to calibrate stepper and scanner mechanisms to account for the optical properties of the purge gas, since conventional 193 nm systems are calibrated to the optical properties of clean dry air.

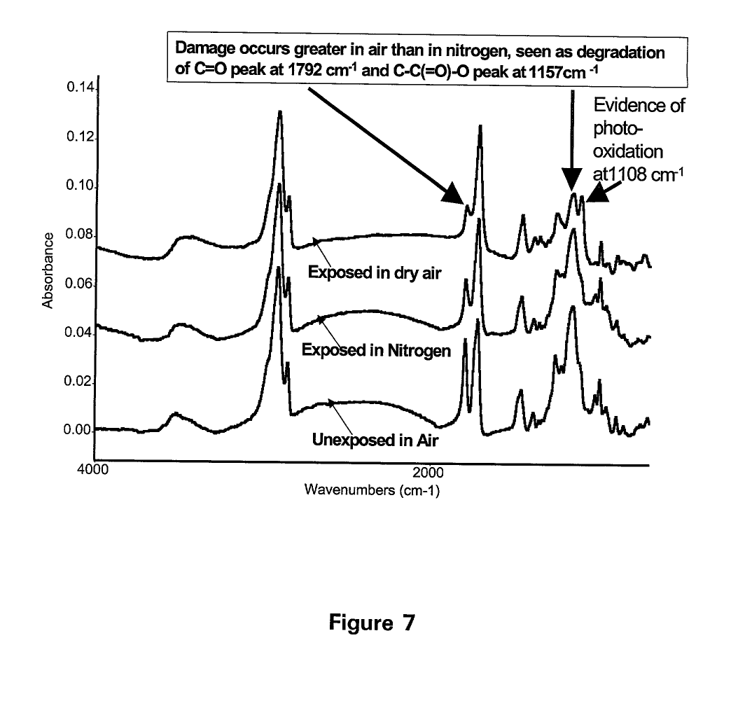

Purging the exposure chamber with nitrogen in accordance with the preferred embodiment reduces photo-induced species erosion of resist features and photo-oxidative degradation and oxidation of patterned feature profiles. FIG. 7 plots the effects on PAR710 photoresist of ArF exposure in dry air and in nitrogen, using unexposed PAR710 as a benchmark. The plots of FIG. 7 show significant decreases in signal peak intensity for the nitrogen signal relative to the dry air signal at around 1792 cm⁻¹, corresponding to the C═O bending vibration, and at around 1157 cm⁻¹, corresponding to the C—C(═O)—O stretching vibration. These decreases indicate that the nitrogen environment reduces photo-oxidative degradation. A further peak in the dry air at around 1108 cm⁻¹ is absent in the signals of the nitrogen sample and the unexposed signal. The presence of this increase only in the signal for the oxygen containing environment indicates that it is represents a further oxidation effect.

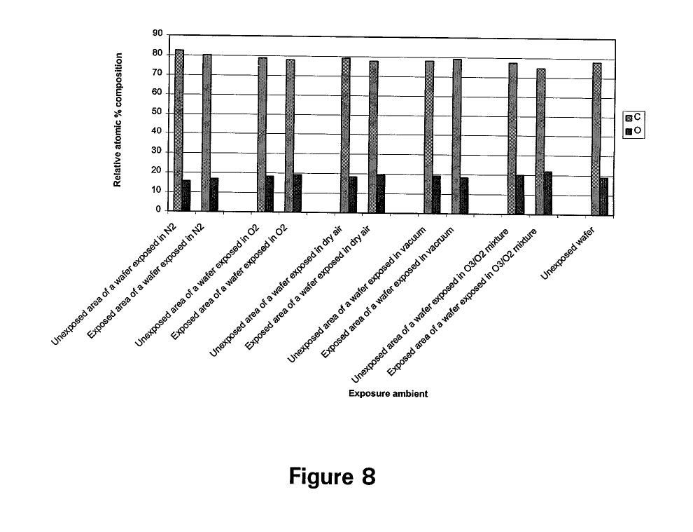

FIG. 8 shows the relative atomic percentages of carbon and oxygen in exposed and unexposed PAR710 resist that has been subjected to various experimental ArF exposure environments. This data demonstrates that the trend in exposure-induced —C—O bonding, relative to the unexposed wafer, is: O₂>O₃/O₂>dry air>N₂>vacuum, which is suggestive of photo-oxidation. The data further indicate that the trend in atomic carbon % composition in the exposed area is: N₂>vacuum>O₂>dry air>O₃/O₂, which suggests that wafers exposed in nitrogen and in a vacuum experience the least photo-oxidative degradation and main chain scission of C—C bonds of the resist polymer relative to wafers exposed in ozone, oxygen and dry air.

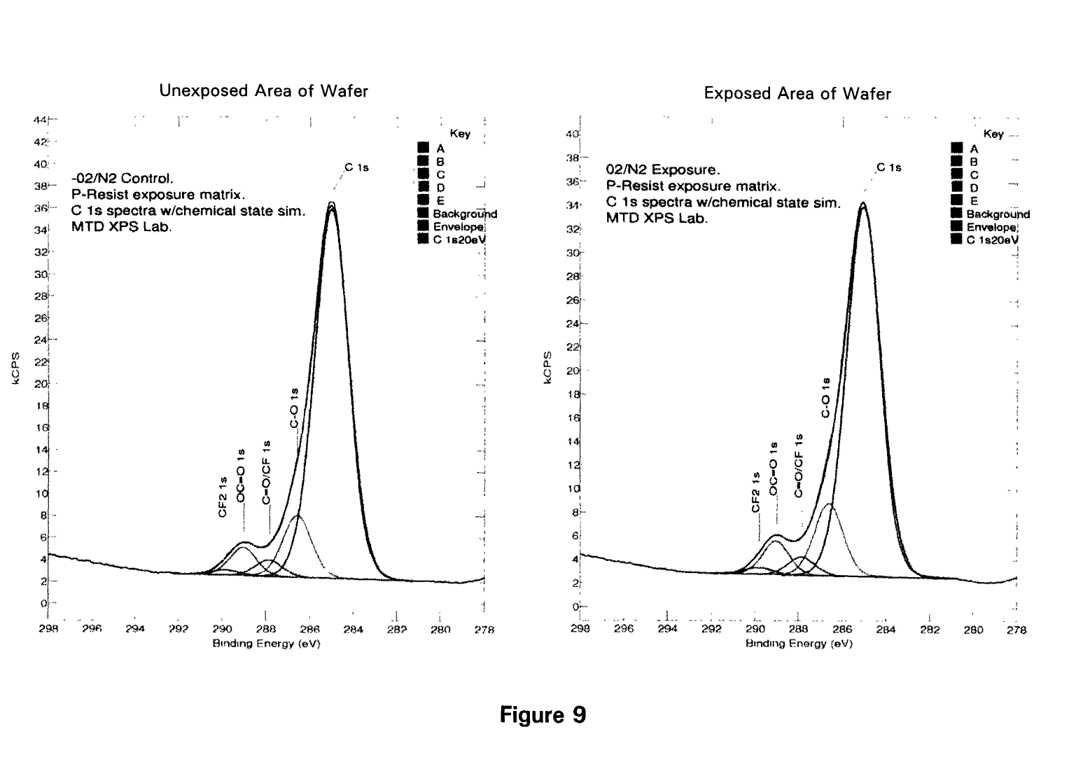

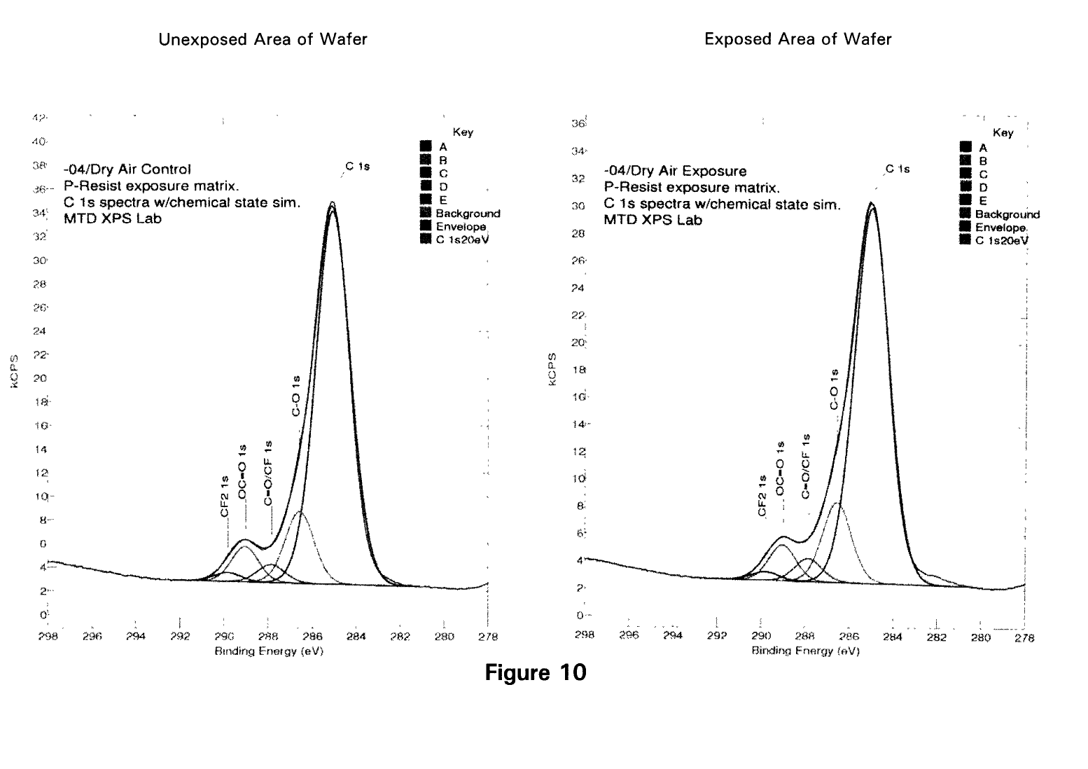

FIG. 9 shows X-ray photo-emission spectra and chemical state simulations of carbon 1 s electrons for a PAR710 resist coated wafer that was subjected to ArF exposure in a nitrogen environment. FIG. 10 shows analogous data for a PAR710 resist coated wafer that was subjected to ArF exposure in a dry air environment. The spectra obtained in the exposed area of the wafer in nitrogen shows a 14% increase in C—O binding peak relative to C—C binding peak.

In view of the above, embodiments in accordance with the invention may reduce oxidative effects in 193 nm photolithography by using a nitrogen purge gas. In alternative embodiments, and inert gas such as argon, neon, krypton, xenon, or helium may be used as a purge gas. In still further embodiments, another gas containing substantially no oxygen may be used as a purge gas. For purposes of this disclosure, a gas is considered to contain substantially no oxygen if it is an industrial grade gas that does not list oxygen as one of its primary constituents. Therefore, an industrial gas containing trace amounts of oxygen is considered to contain substantially no oxygen within the meaning of the present disclosure.

In accordance with one embodiment of the invention, a 193 nm projection lithography system includes an exposure section containing a stage for supporting a substrate and a projection optical system for projecting a pattern toward the stage. The lithography system may include a stepper for moving the stage and a scanner for moving the projected pattern. The system further includes a purge gas delivery system comprising a source of a purge gas containing substantially no oxygen. The purge gas reduces the amount of oxygen species induced by the 193 nm radiation in the exposure section. In a preferred embodiment, the purge gas is nitrogen. In a further preferred embodiment, a scanner and a stepper may be calibrated to the optical properties of the purge gas atmosphere.

In accordance with a further embodiment of the invention, a method for performing projection lithography comprises providing a lithography system having an exposure section, providing a substrate comprising a photoresist layer in the exposure section, and exposing the photoresist layer to 193 nm radiation while purging the exposure section with a purge gas containing substantially no oxygen. The purge gas is preferably nitrogen. The method may further comprise calibrating a scanner or a stepper of the lithography system to the optical properties of the purge gas atmosphere prior to exposure.

In accordance with a further embodiment of the invention, a layer of a protective material may be formed over a photoresist layer prior to exposure to protect the photoresist layer from any oxygen species within the exposure portion of the lithography system. Such oxygen species could come from trace amounts of oxygen that may be present in a nitrogen atmosphere, or could come from other sources as described above when a conventional clean dry air atmosphere is employed. The protective coating may be stripped after exposure prior to post-exposure baking and development, or it may be baked and developed with the photoresist.

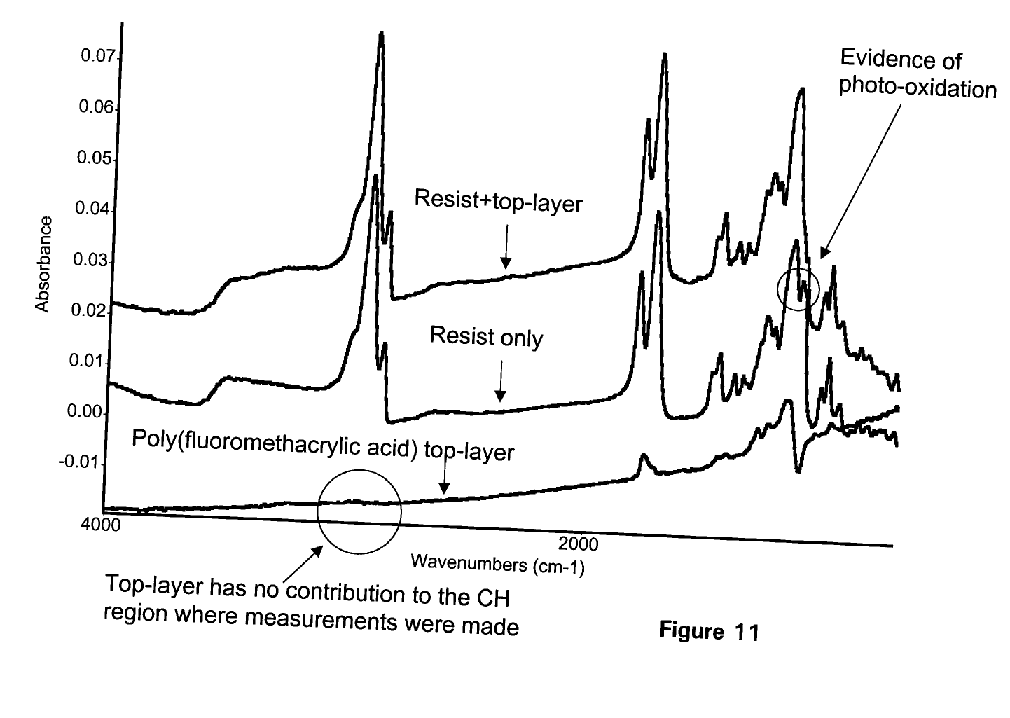

In accordance with one preferred embodiment of the invention, a protective layer of a poly(fluoromethacrylic acid) film is provided over a photoresist layer. Various species of such compounds are conventionally used as spin-on antireflective coatings over photoresist during exposure. FIG. 11 shows FTIR spectra after 193 nm exposure in dry air for a polyfluoroalkyl acrylate layer, a bare PAR700 photoresist layer, and a PAR700 photoresist layer protected by a layer of poly(fluoromethacrylic acid) film. As seen in FIG. 11, peaks at wavelengths characteristic of oxidation are present in the bare photoresist signal but not in the other signals. This indicates that the poly(fluoromethacrylic acid) film is not oxidized by the oxygen species in the exposure atmosphere. Other compounds may also be utilized as sacrificial protective layers in alternative embodiments. Preferred alternative compounds include thin (10-50 nm) film of polymethyl methacrylic acid, poly(bicyclo[2.2.1]hept-5-ene-2-carboxylic acid), and poly(bicyclo[2.2.1]hept-5-ene-2-carboxylic acid-alt-maleic anhydride). Other suitable hydrophilic polymers include, but are not limited to polymers and copolymers of: alpha.,.beta.-monoethylenically unsaturated monomers containing acid functionality, including monomers containing at least one carboxylic acid group including acrylic acid, methacrylic acid, (meth)acryloxypropionic acid, itaconic acid, maleic acid, maleic anhydride, fumaric acid, crotonic acid, monoalkyl maleates, monoalkyl fumerates and monoalkyl itaconates; acid substituted (meth)acrylates, sulfoethyl methacrylate and phosphoethyl (meth)acrylate; acid substituted (meth)acrylamides, such as 2-acrylamido-2-methylpropylsulfonic acid and ammonium salts of such acid functional and acid-substituted monomers; basic substituted (meth)acrylates and (meth)acrylamides, such as amine substituted methacrylates including dimethylaminoethyl methacrylate, tertiary-butylaminoethyl methacrylate and dimethylaminopropyl methacrylamide; acrylonitrile; (meth)acrylamide and substituted (meth)acrylamide, such as diacetone acrylamide; (meth)acrolein; and methyl acrylate.

While the aforementioned embodiments described herein are presently preferred, it should be understood that these embodiments are offered by way of example only. The invention is not limited to a particular embodiment, but extends to various modifications, combinations, and permutations that fall within the scope and spirit of the appended claims.

What is claimed is:

1. A projection lithography system comprising:
an exposure section;
a stage located in the exposure section for supporting a photoresist coated substrate;
a 193 nm radiation source;
a projection optical system for projecting a pattern of said 193 nm radiation toward said platform; and
a gas delivery system for providing a purge gas to the exposure section, the gas delivery system including a purge gas source providing a purge gas containing substantially no oxygen to thereby reduce an amount of oxygen species induced by the 193 nm radiation in the exposure section.

2. The system claimed in claim 1, further comprising a stepper calibrated to the optical properties of the purge gas.

3. The system claimed in claim 1, further comprising a scanner calibrated to the optical properties of the purge gas.

4. The system claimed in claim 1, wherein the purge gas comprises at least one of nitrogen and an inert gas.

5. The system claimed in claim 4, further comprising a stepper calibrated to the optical properties of the purge gas.

6. The system claimed in claim 4, further comprising a scanner calibrated to the optical properties of the purge gas.

7. A method of performing photolithography, comprising:
providing a 193 nm lithography system having an exposure section;
providing a substrate comprising a photoresist layer in the exposure section; and
exposing the photoresist layer to 193 nm radiation while purging the exposure section with a purge gas containing substantially no oxygen to thereby reduce an amount of oxygen species induced by the 193 nm radiation in the exposure section.

8. The method claimed in claim 7, wherein providing the substrate is preceded by calibrating a stepper of the lithography system to the optical properties of the purge gas.

9. The method claimed in claim 7, wherein providing the substrate is preceded by calibrating a scanner of the lithography system to the optical properties of the purge gas.

10. The method claimed in claim 7, wherein the purge gas is nitrogen.

11. The method claimed in claim 10, wherein providing the substrate is preceded by calibrating a stepper of the lithography system to the optical properties of the nitrogen purge gas.

12. The method claimed in claim 10, wherein providing the substrate is preceded by calibrating a scanner of the lithography system to the optical properties of the nitrogen purge gas.

13. The method claimed in claim 7, wherein the purge gas is an inert gas.

14. The method claimed in claim 13, wherein providing the substrate is preceded by calibrating a stepper of the lithography system to the optical properties of the inert purge gas.

15. The method claimed in claim 13, wherein providing the substrate is preceded by calibrating a scanner of the lithography system to the optical properties of the inert purge gas.

16. The method claimed in claim 7, wherein the substrate further comprises a protective layer formed over the photoresist layer.

17. The method claimed in claim 16, wherein said protective layer comprises poly(fluoromethacrylic acid).

18. The method claimed in claim 16, wherein said protective layer comprises polymethyl methacrylic acid

19. The method claimed in claim 16, wherein said protective layer comprises one of poly(bicyclo[2.2.1]hept-5-ene-2-carboxylic acid) and poly(bicyclo[2.2.1]hept-5-ene-2-carboxylic acid-alt-maleic anhydride).

20. The method claimed in claim 16, wherein said protective layer comprises one of:
polymers and copolymers of alpha.,.beta.-monoethylenically unsaturated monomers containing acid functionality, including monomers containing at least one carboxylic acid group including acrylic acid, methacrylic acid, (meth)acryloxypropionic acid, itaconic acid, maleic acid, maleic anhydride, fumaric acid, crotonic acid, monoalkyl maleates, monoalkyl fumerates and monoalkyl itaconates;
acid substituted (meth)acrylates, sulfoethyl methacrylate and phosphoethyl (meth)acrylate;
acid substituted (meth)acrylamides, such as 2-acrylamido-2-methylpropylsulfonic acid and ammonium salts of such acid functional and acid-substituted monomers;
basic substituted (meth)acrylates and (meth)acrylamides, such as amine substituted methacrylates including dimethylaminoethyl methacrylate, tertiary-butylaminoethyl methacrylate and dimethylaminopropyl methacrylamide;
acrylonitrile;
(meth)acrylamide and substituted (meth)acrylamide, such as diacetone acrylamide; (meth)acrolein; and
methyl acrylate.
